(19) United States
(12) Patent Application Publication
(10) Pub. No.: US 2014/0110768 A1
(43) Pub. Date: Apr. 24, 2014

(54) TRANSISTOR DEVICE

(71) Applicant: Keystone Semiconductor Corp., Hsinchu (TW)

(72) Inventor: Chao-Sung Lin, Hsinchu (TW)

(21) Appl. No.: 13/938,082

(22) Filed: Jul. 9, 2013

(30) Foreign Application Priority Data
Oct. 18, 2012 (TW) 101138456

(51) Int. Cl. H01L 29/78

(52) U.S. Cl. CPC H01L 29/78
USPC 257/288

(57) ABSTRACT

A transistor device includes a semiconductor substrate, a gate structure, and first and second metal layers. The semiconductor substrate includes a substrate body having a plurality of drain and source regions alternately arranged in a checkerboard pattern and spaced apart from each other. The first metal layer is disposed on the substrate body and includes a plurality of first pattern elements and a first patterned region. The second metal layer is disposed on top of the first metal layer and has a plurality of second pattern elements and a second patterned region.

### CROSS-REFERENCE TO RELATED APPLICATION

This application claims priority of Taiwanese Application No. 101138456, filed on Oct. 18, 2012.

### BACKGROUND OF THE INVENTION

1. Field of the Invention

The invention relates to a transistor device, more particularly to a transistor device for a power transistor integrated circuit.

2. Description of the Related Art

Referring to FIGS. 1 and 2, a conventional transistor device 1 adapted for a power transistor integrated circuit (such as a DC-DC converter integrated circuit) includes a semiconductor substrate 11, a plurality of gate electrodes 12 and a metal layer structure 13.

The semiconductor substrate 11 includes a substrate body 111 and a plurality of source and drain regions 112 and 113 that are alternately arranged and that are parallel and spaced apart from each other.

The gate electrodes 12 are disposed on a top surface of the semiconductor substrate 11 and between each adjacent pair of the source and drain regions 112 and 113. Each of the gate electrodes 12 has a dielectric layer 121 that is formed on the top surface of the semiconductor substrate 11 and an electrode layer 122 that is formed on the dielectric layer 121.

The metal layer structure 13 includes a first metal layer 131, a second metal layer 132, and a via layer

133 disposed between the first and second metal layers 131 and 132.

The first metal layer 131 includes a plurality of first and second strip regions 134 and 136 that are disposed on top of the corresponding source and drain regions 112 and 113. The second rectal layer 132 includes third and fourth strip regions 135 and 137 that are disposed on the first and second strip regions 134 and 136 and that extend in a transverse direction transverse to the first and second strip regions 134 and 136. The third scrip region 135 of the second metal layer 132 is electrically connected to the first strip regions 134 which are electrically connected to the corresponding source regions 112. The fourth strip region 137 is electrically connected to the second strip regions 136 which are electrically connected to the corresponding drain regions 113. The electrical connection between the first and third strip regions 134 and 135, as well as the electrical connection between the second and fourth strip regions 136 and 137, is achieved using the via layer 133.

Each of the gate electrode 12 together with the adjacent pair of the source and drain regions 112 and 113 defines a transistor. That is, the gate electrodes 12 and the source and drain regions 112 and 113 define a plurality of parallel-arranged transistors that are electrically connected.

When the electrode layer 122 of each or the gate electrodes 12 receives a gate voltage (V_{g}) from an exterior power supply and the third and fourth strip regions 135 and 137 of the second metal layer 132 receive an input voltage (V_{d}), resulting in that voltage V_{GS} (or V_{GS} for the P-type MOSFET) between the source region 112 and the gate electrode 12 is greater than a threshold voltage Vₜₕ and a channel is thus formed in the substrate body 111 under the gate electrode 12, so as to turn on the respective transistor (i.e., the respective source and drain regions 112, 113 are electrically connected to each other through the formed channel).

Generally, there are two ways to improve the power efficiency of the power transistor integrated circuit that contains the conventional transistor device 1: (a) forming more drain and source regions 113 and 112 as well as the gate electrodes 12 along the transverse direction to define more transistors that are parallel arranged in one conventional transistor device; and (b) incorporating more conventional transistor devices that are parallel arranged to form a transistor matrix array into the power transistor integrate circuit (see FIG. 3).

However, the widths of the third and fourth strip regions 135 and 137 are limited to the lengths of the gate electrodes 12, and the resulting overlapping areas between the third or fourth strip region 135 and 137 and the first or second strip region 134 and 136 are too small that considerable parasitic resistances are generated. Thus, the power efficiency of the conventional transistor device 1 in either way becomes lower.

### SUMMARY OF THE INVENTION

Therefore, the object of the present invention is to provide a transistor device that may alleviate the aforesaid drawback.

Accordingly, a transistor device of the present invention includes:

a semiconductor substrate including a substrate body having a plurality of drain regions and source regions, the drain and source regions being spaced apart and alternately arranged in rows and columns to form a checkerboard pattern, and spaced apart from each other;

a gate structure disposed on the semiconductor substrate and including a plurality of intersecting gate electrodes that are electrically interconnected, each of the gate electrodes being arranged between a corresponding adjacent pair of the drain and source regions;

a first metal layer disposed on the substrate body, and including a plurality of spaced-apart first pattern elements and a first patterned region, each of the first pattern elements being electrically connected to a respective one of the drain regions, the first patterned region surrounding each of the first pattern elements being free of contact with the first pattern elements and being electrically connected to the source regions; and

a second metal layer disposed on top of the first metal layer, and having a plurality of spaced-apart second pattern elements, and a second patterned region, the second pattern elements being electrically connected to the first patterned region of the first metal layer, the second patterned region surrounding each of the second pattern elements, being free of contact with the second pattern elements, and being electrically connected to the first pattern elements of the first metal layer.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional transistor device;

FIG. 2 is a sectional view of the conventional transistor device;

FIG. 3 is a perspective view of two conventional transistor devices that are parallel arranged;

FIG. 4 is a partly exploded view of a first preferred embodiment of a transistor device according to the present invention;

FIG. 5 is a sectional view of the first preferred embodiment; and

FIG. 6 is a sectional view of a second preferred embodiment of the transistor device according to the present invention.

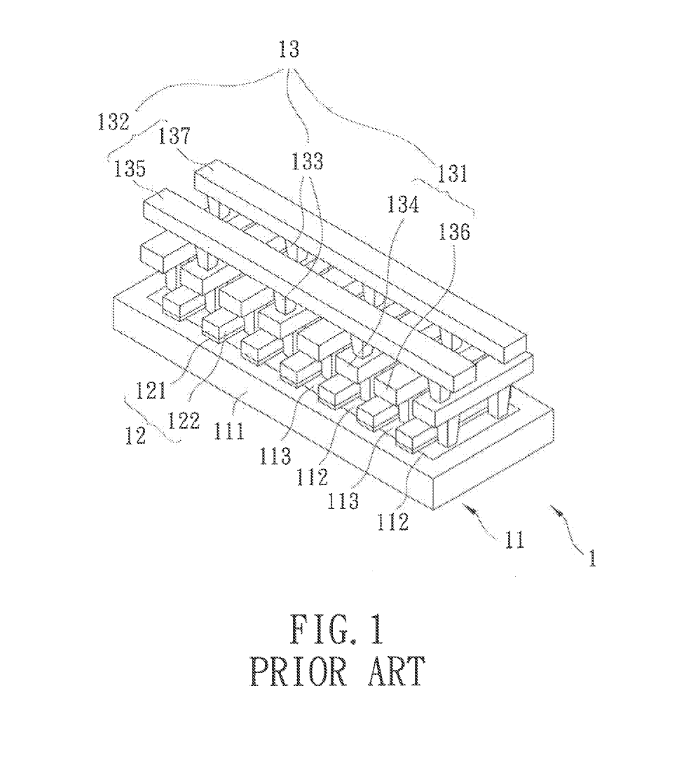

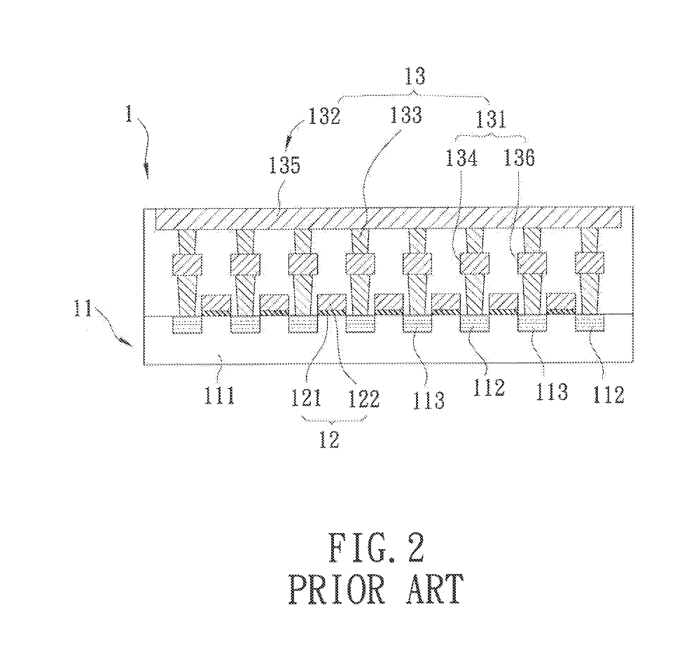

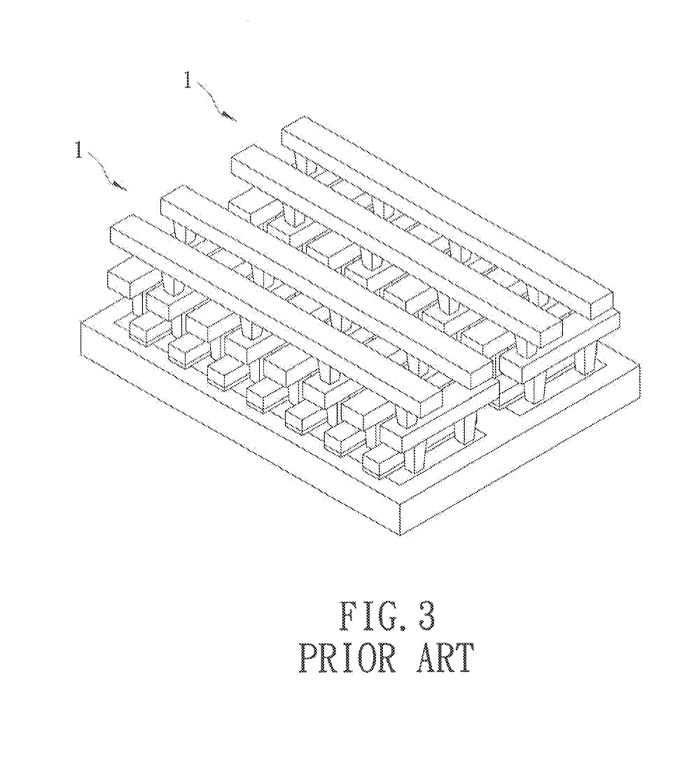

### DETAILED DESCRIPTION OF THE PREFERRED EMBODIMENTS

Before the present invention is described in greater detail, it should be noted that like elements are denoted by the same reference numerals throughout the disclosure.

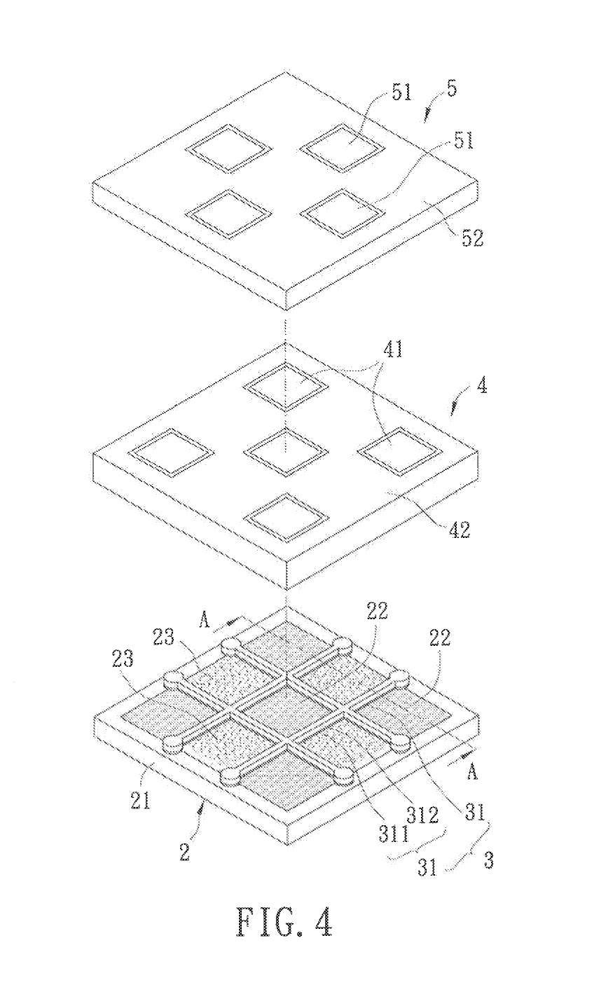

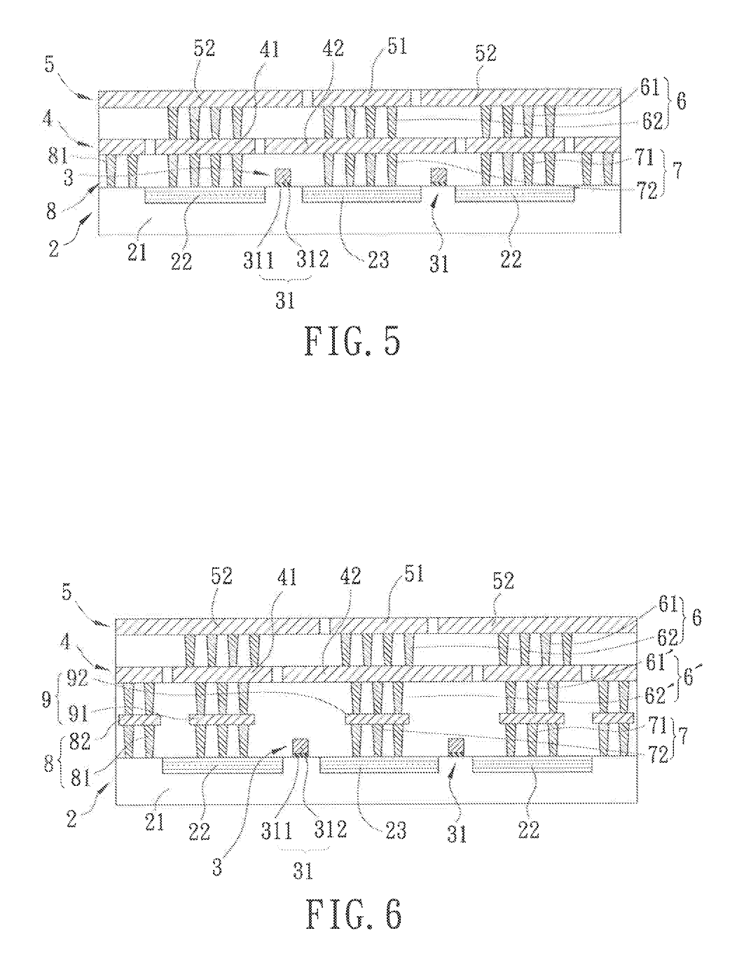

As shown in FIGS. 4 and 5, the first preferred embodiment of a transistor device according to the present invention is shown to include a semiconductor substrate 2, a gate structure 3, a first metal layer 4, a second metal layer 5, a via layer 6, and a contact layer 7.

The semiconductor substrate 2 is substantially made of a semiconductor material, e.g., silicon, germanium, or group III-V semiconductor materials. The semiconductor substrate 2 includes a substrate body 21 having a plurality of drain regions 22 and source regions 23. The drain and source regions 22 and 23 are spaced-apart from each other and alternately arranged in rows and columns to form a checkerboard pattern.

When the substrate body 21 has one of n-type and p-type semiconductor characteristics, the drain and source regions 22 and 23 have the other one of the n-type and P-type semiconductor characteristics. That is, when the substrate body 21 is n-type, the drain regions 22 and the source regions 23 are p-type. In this embodiment, the substrate body 21 is p-type, and the source and drain regions 23 and 22 are n-type. in this embodiment, the semiconductor substrate 2 has five drain regions 22 and four source regions 23, and the drain and source regions 22 and 23 are arranged in a 3×3 matrix array that is configured substantially in a rectangular shape. One of the drain regions 23 is located in the center of the 3×3 matrix array.

The gate structure 3 is disposed on the semiconductor substrate 2 and includes a plurality of intersecting gate electrodes 31 that are electrically interconnected. Each of the gate electrodes 31 is disposed between a corresponding adjacent pair of the drain and source regions 22 and 23. Each of the gate electrodes 31 includes a dielectric layer 311 formed on a top surface of the semiconductor substrate 2 and an electrode layer 312 that is formed on top of the dielectric layer 311. The gate electrodes 31 are electrically interconnected and are disposed for receiving a common gate voltage (V_{g}). Each of the gate electrodes 31 along with one of the adjacent source regions 23 and the corresponding one of the adjacent drain regions 22 defines a transistor. In this preferred embodiment, the 3×3 matrix array of the drain and source regions 22 and 23 together with the total 12 gate electrodes define 12 transistors that are electrically interconnected.

The first metal layer 4 is disposed on top of the semiconductor substrate 2 and includes a plurality of spaced-apart first pattern elements 41 and a first patterned region 42. Each of the first pattern elements 41 is electrically connected to a respective one of the drain regions 22. The first patterned region 42 surrounds each of the first pattern elements 41 without contacting the first pattern elements 41 (i.e., free of contact with the first pattern elements 41) and is electrically connected to the source regions 23. More specifically, the first patterned region 42 defines a plurality of cavities, and the first pattern elements 41 are located in the corresponding cavities without contacting the first patterned region 42.

The second metal layer 5 is disposed on top of the first metal layer 4 and has a plurality of spaced-apart second pattern elements 51 and a second patterned region 52. The second pattern elements 51 are electrically connected to the first patterned region 42 of the first metal layer 4. The second patterned region 52 surrounds each of the second pattern elements 51 without contacting the second pattern elements 51 (i.e., free of contact with the second pattern elements 51) and is electrically connected to the first pattern elements 41 of the first metal layer 4, More specifically, the second patterned region 52 defines a plurality of cavities, and the second pattern elements 51 are located in the corresponding cavities without contacting the second patterned region 52.

The via layer 6 is disposed between the first and second metal layers 4 and 5 and includes a plurality of first and second vias 61 and 62. The first vias 61 electrically connect the first pattern elements 41 and the second patterned region 52. The second vias 62 electrically connect the first patterned region 42 and the second pattern elements 51.

The contact layer 7 is disposed between the semiconductor substrate 2 and the first metal layer 4 and includes a plurality of first and second contacts 71 and 72. The first contacts 71 electrically connect the drain regions 22 and the first pattern elements 41, The second contacts 72 electrically connect the source regions 23 and the first patterned region 42.

In this embodiment, the transistor device further includes a bulk contact unit 8 that is formed on the top surface of the semiconductor substrate 2 and surrounds the drain and source regions 22 and 23. The bulk contact unit 8 includes a plurality of bulb contacts 81 electrically connected to the substrate body 21 for being provided with a substrate voltage (V_{b}) from an exterior power supply. In this embodiment, since the source regions 23 and the bulk contact unit 8 generally are electrically interconnected and equipotential, a peripheral part of the first patterned region 42 is also electrically connected to the bulk contact unit 8.

It also worth noting that if the substrate body 21 is a p-type semiconductor layer such as a p-type epitaxial layer, the bulk contact unit 8 may further include a p+ region which is formed in the substrate body 21, which is electrically connected to the bulk contacts 81, and which has a higher concentration of p-type dopants. On the other hand, if the substrate body 21 is a n-type semiconductor layer such as a n-type epitaxial layer, the bulk contact unit 8 may further include a n+ region which is formed in the substrate body 21, which is electrically connected to the bulk contacts 81, and which has a higher concentration of the n-type dopants.

When the second, patterned region 52 receives the input voltage (V_{d}) relative to the second pattern elements 51, the bulk contact unit 8 receives the substrate voltage (V_{b}), and the gate structure 3 receives the common gate voltage (V_{g}), the transistors are turned into an ON state. When the second patterned region 52 of the second metal layer 5 does not receive the input voltage (Vd) relative to the second pattern elements 51, the transistors of the transistor device according to the present invention are in an OFF state.

In this invention, the dimension of the first patterned region 42 only needs to be large enough to cover ail the source regions 23 and is not limited to the lengths and widths of the gate electrodes 31. Similarly, the second patterned region 52 of the second metal layer 5 only needs to be disposed on top of the first metal layer 4 and is not limited to the dimensions of the first patterned region 41 and the gate electrodes 31. Therefore, the parasitic resistances between the first pattern elements 41, which electrically connects to the drain regions 22, and the second patterned region 52 of the second metal layer 5 are effectively lowered due to relatively large connecting areas, as well as those between the first patterned region 42, which connects to the source regions 23, and the second pattern elements 51. Such lowered parasitic resistances may reduce the power consumption of the transistor device and waste heat generated therefrom, so as to greatly enhance the power efficiency of the transistor device according to the present invention and to alleviate the overheating problem thereof.

Referring to FIG. 6, the second preferred embodiment of the transistor device according to the present invention is shown to include a structure similar to that of the first preferred embodiment. The difference between the first and the second preferred embodiments resides in that the second preferred embodiment of the transistor device further includes a third metal layer 9 and a second via layer 6′.

The third metal layer 3 is disposed between the first metal layer 4 and the contact layer 7 and includes a plurality of third and fourth patterned regions 91 and 92 which are electrically connected to the corresponding source and drain regions 22 and 23 via the corresponding first and second contacts 71 and 72.

The second via layer 6′ is disposed between the first and third metal layers 4 and 9 and includes a plurality of first and second vias 61′ and 62′ that are electrically connected to the corresponding first patterned region 41 and first pattern elements 42, and that are also electrically connected to the third and fourth pattern regions 91 and 92 which are electrically connected to the corresponding source and drain regions 23 and 22 respectively.

In this embodiment, the bulk contact unit 8 may include at least one bulk contact 81 and a surrounding metal layer 82 that is formed in the same metal loop process as the third metal layer 9. The at least one bulk contact 81 is electrically connected to the substrate body 21 for being provided with the substrate voltage (V_{b}) from the exterior power supply. The second preferred embodiment has the same advantages as those of the first preferred embodiment. Further, the presence of the third metal layer 9 ensures even distribution of the applied input voltage (V_{d}) throughout the drain regions 22, so as to lower the resistance of the transistor device.

To sum up, the checkerboard pattern design of the source and drain regions 23 and 22 allows the structures of the first and second metal layers 4 and 5 not to be limited to the conventional strip shape with small widths, so as to effectively lower the parasitic resistances generated between the first and second metal layers 4 and 5.

While the present invention has been described in connection with what are considered, the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A transistor device comprising:
a semiconductor substrate including a substrate body having a plurality of drain regions and source regions, said drain and source regions being spaced apart and alternately arranged in rows and columns to form a checkerboard pattern;
a gate structure disposed on said semiconductor substrate and including a plurality of intersecting gate electrodes that are electrically interconnected, each of said gate electrodes being arranged between a corresponding adjacent pair of said drain and source regions;
a first metal layer disposed on said substrate body, and including a plurality of spaced-apart first pattern elements and a first patterned region, each of said first pattern elements being electrically connected to a respective one of said drain regions, said first patterned region surrounding each of said first pattern elements, being free of contact with said first pattern elements, and being electrically connected to said source regions; and
a second metal layer disposed on top of said first metal layer, and having a plurality of spaced-apart second pattern elements, and a second patterned region, said second pattern elements being electrically connected to said first patterned region of said first metal layer, said second patterned region surrounding each of said second pattern elements, being free of contact with said second pattern elements, and being electrically connected to said first pattern elements of said first metal layer.

2. The transistor device as claimed in claim 1, further comprising a bulk contact formed on said substrate body around said source and drain regions to provide a substrate voltage to said substrate body.

3. The transistor device as claimed in claim 1, further comprising a via layer disposed between said first and second metal layers and including a plurality of first and second vias, said first vias electrically connecting said first pattern elements and said second patterned region, said second vias electrically connecting said first patterned region and said second pattern elements.

4. The transistor device as claimed in claim 3, further comprising a third metal layer disposed between said semiconductor substrate and said first metal layer and including a plurality of third, and fourth patterned regions, said third patterned regions of said third metal layer electrically connecting said drain regions and said first pattern elements of said first metal layer, said fourth patterned regions ox said third metal layer being electrically connected to said source regions and said first patterned region of said first metal layer.

5. The transistor device as claimed in claim 1, wherein said substrate has five drain regions and four source regions, said drain and source regions being arranged in a 3×3 matrix array.

6. The transistor device as claimed in claim 1, wherein each of said gate electrodes of said gate structure has a dielectric layer formed on a top surface of said substrate body, and an electrode layer formed on top of said dielectric layer,

7. The transistor device as claimed in claim 1, wherein said substrate body has one of n-type and p-type semiconductor characteristics, said source and drain regions having the other one of the n-type and p-type semiconductor characteristics.
